(19) United States
(12) Patent Application Publication
(10) Pub. No.: US 2026/0313855 A1
(43) Pub. Date: Oct. 8, 2026

(54) DEVICE AND METHOD FOR DISSIPATING HEAT FROM AN ELECTRONIC COMPONENT OF A MOTOR VEHICLE

(71) Applicant: Robert Bosch GmbH, Stuttgart (DE)

(72) Inventors: Juergen Kossack, Ludwigsburg (DE); Manuel Maul, Keltern (DE)

(21) Appl. No.: 19/481,312

(22) PCT Filed: May 7, 2024
(86) PCT No.: PCT/EP2024/062571

§ 371 Date: Nov. 4, 2025

(30) Foreign Application Priority Data
Jun. 13, 2023 (DE) 10 2023 205 498.1

(51) Int. Cl. H05K 7/20

(52) U.S. Cl. CPC H05K 7/20854; H05K 7/20418

(57) ABSTRACT

A device and a method for dissipating heat from an electronic component of a motor vehicle. The device includes at least one cooler having at least one connection face which is configured such that via the connection face heat may be dissipated from the electronic component arranged on a circuit board, including at least one housing which at least partially encloses the circuit board, wherein the housing has at least one housing opening, wherein at least a portion of the cooler extends out of this housing opening, wherein a gap dimension between the electronic component and the connection face is configured to be able adjustable to different steps via at least one stepped arrangement.

### FIELD

The present invention relates to a device and a method for dissipating heat from an electronic component of a motor vehicle.

### BACKGROUND INFORMATION

Germany Patent Application No. DE 10 2013 206 999 A1 describes a control unit for a motor vehicle with a heat-conducting housing wall which is formed from a thermally conductive sheet and forms a heat sink. The heat-conducting housing wall is detachably connected to the housing and has, in a region arranged opposite the power semiconductor, an embossment, wherein, by means of the embossment, the housing wall is brought closer to the power semiconductor, such that a distance, in particular, a gap dimension, between the housing wall and the power semiconductor before embossing is greater than a distance, in particular, a distance between the housing wall and the surface region following the embossing.

An object of the present invention is to ensure reliable heat dissipation of the electronic component. This object may be achieved by certain features of the present invention.

### SUMMARY

Because a gap dimension between the electronic component and the connection face is configured to be adjustable in different steps using at least one stepped arrangement, the suitable gap dimension, in particular, a small one, may be adjusted in a targeted and particularly simple manner for each specific configuration of a control unit. As a result, an efficient thermal connection of the electronic component from which heat is to be dissipated, to the cooler of the control unit may be achieved. At the same time, a stable or rigid system may be produced which does not result in any deterioration of the vibration load on the control unit.

In an advantageous development of the present invention, it is provided that the stepped arrangement is arranged on the cooler and/or on the electronic component and/or on the housing and/or on a component connected to the electronic component, in particular, a circuit board. This yields, depending on the specific configuration of the particular control unit, a high degree of design flexibility.

In an advantageous development of the present invention, at least one mating surface is provided which interacts with the stepped arrangement to adjust the gap dimension, wherein the mating surface is located on the cooler and/or on the electronic component and/or on the housing and/or on a component connected to the electronic component, in particular, on a circuit board. In this way, low mechanical effort may be achieved with high stability.

More preferably, according to an example embodiment of the present invention, the stepped arrangement comprises a plurality of steps and/or plateaus and/or offsets and/or a further stepped arrangement. This makes it possible to carry out an adjustment of the gap dimension perpendicular to the surface of the housing.

In an advantageous development of the present invention, the stepped arrangement comprises a plurality of steps of different height. This makes it possible, depending on the application and requirements, to carry out a sufficiently precise and simple adjustment of the gap dimension.

In an advantageous development of the present invention, it is provided that the gap dimension is adjustable by a relative movement between the cooler and the housing and/or between the mating surface and the stepped arrangement. This also makes it particularly easy to carry out the corresponding adjustment by machine. Particularly advantageously, the relative movement takes place by means of a linear and/or planar movement parallel to the surface of the connection face and/or by means of a rotation. The desired relative movement may be achieved depending on the installation situation or the manufacturing equipment.

In an advantageous development of the present invention, it is provided that, along the relative movement, particularly in the case of a linear movement and/or a rotation, the height of the steps of the stepped arrangement and/or of the further stepped arrangement changes discretely, in particular, increases or decreases. In this way, a particularly simple adjustment of the desired gap dimension may be achieved.

In an advantageous development of the present invention, it is provided that the stepped arrangement and/or the mating surface interacting with the stepped arrangement is arranged on an rim of the cooler covering the housing opening. This allows a particularly simple and stable adjustment of the gap dimension to be made, and additionally provides a geometric possibility for an integrated sealing of the control unit.

In an advantageous development of the present invention, the mating surface interacting with the stepped arrangement is formed to project relative to the surface in such a way that this mating surface may cover at least parts of the stepped arrangement. This makes it possible to achieve a particularly simple and stable design, in particular of the cooler.

In an advantageous development of the present invention, it is provided that, following adjustment of the desired gap dimension, at least one connecting means is provided for fixing the cooler relative to the electronic component, wherein the connecting means interacts with an oversized through-hole or elongated hole. Thus, different fastening positions of the fastening means relative to the cooler may be accommodated, depending on the extent of the relative movement of the cooler relative to the electronic component. The offset may be easily compensated. The stability of the arrangement is further increased.

Through the further method steps, the manufacturing process may be further automated in a particularly simple manner, increasing flexibility for different installation heights or geometries of the electronic component.

Other further advantageous developments of the present invention will emerge from the disclosure herein.

### BRIEF DESCRIPTION OF THE DRAWINGS

FIG. 1 shows an overall illustration of a control unit in a side view, according to an example embodiment of the present invention.

FIG. 2 shows a schematic representation of a gap adjustment by lateral offset, according to an example embodiment of the present invention.

FIG. 3 shows a top view of a linearly displaceable cooler, according to an example embodiment of the present invention.

FIG. 4 shows a top view of a rotatably adjustable cooler, according to an example embodiment of the present invention.

### DETAILED DESCRIPTION OF EXAMPLE EMBODIMENTS

The present invention is illustrated schematically using an exemplary embodiment and is described in detail in the following with reference to the figures.

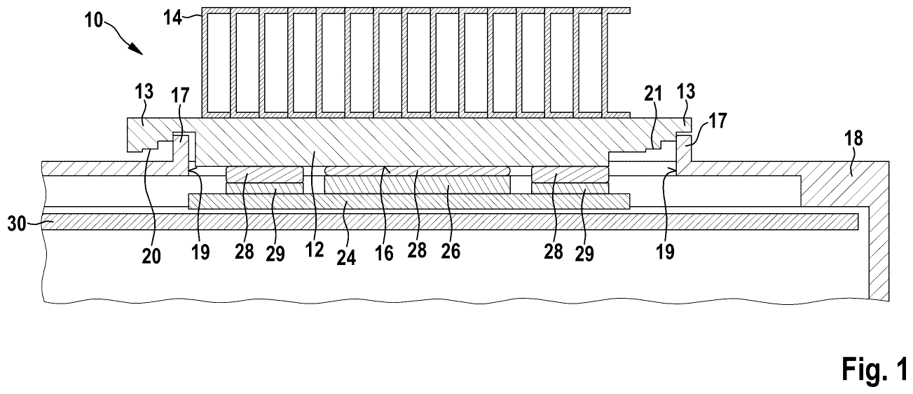

In FIG. 1, a control unit 10 is shown in side view. By way of example, on a circuit board 24, an electronic component 26 from which heat is to be dissipated is arranged approximately in the center. By way of example, additional electronic components 29 from which heat is likewise to be dissipated are arranged on the circuit board 24; however, these are characterized by a lower power loss than the electronic component 26, from which heat is to be dissipated particularly reliably or with a particularly low heat transfer resistance. For example, the electronic component 26 may be a so-called SIP (System-in-Package) or a component thereof and/or a so-called System-on-Chip (SoC) or another semiconductor with high power loss.

The circuit board 24 may be arranged or soldered on another circuit board 30, for example, the main board. In addition, depending on the application, further circuit boards 24 having at least one electronic component 26 that likewise generates a high power loss may be provided on the further circuit board 30.

Thus, for example, the circuit board 24 configured as an SIP, which includes an SoC as the electronic component 26, may be soldered onto the circuit board 30.

The circuit board 24 and/or the further circuit board 30 may be at least partially enclosed by a housing 18. To this end, the circuit board 24 and/or the further circuit board 30 is/are connected to the housing 18. The housing 18 has an opening 19. A cooler 12 is accommodated at least partially in this opening 19. The cooler 12 projects slightly outward beyond the surface of the housing 18, such that particularly good heat dissipation becomes possible. For example, the housing 18 may be a die-cast housing, but may also be a sheet-metal housing, a plastic housing, or the like.

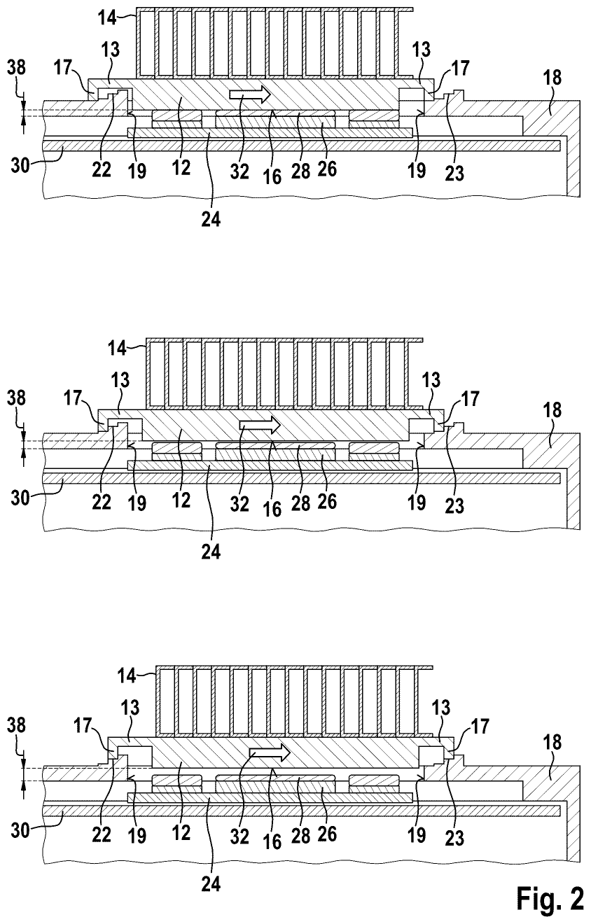

The cooler 12 serves for dissipating heat from at least the electronic component 26 or also from further electronic components 29. In this case, the electronic component 26, 29 is thermally coupled to the cooler 12 via a thermally conductive material 28 in order to minimize the thermal transfer resistance. In this case, the thermally conductive material 28 is arranged between the electronic component 26, 29 and a connection face 16 on the cooler 12 for the thermal coupling of the cooler 12 to the electronic component 26 from which heat is to be dissipated. The connection face 16 is divided into two regions, namely the one having the smallest gap dimension 38, the TIM gap (gap for TIM material, TIM meaning thermal interface materials or thermally conductive material 28; for example, thermal pastes or flexible materials in the form of a cushion or pad, etc.) relative to the electronic component 26, and the outer region, which serves, via thermally conductive material 28, for the dissipation of heat from the further electronic components 29. Between the connection face 16 and the surface of the electronic component 26 from which heat is to be dissipated, a gap dimension 38 to be minimized forms, as shown in FIG. 2. The smaller this gap dimension 38 is, the more effectively the power loss of the electronic component 26 may be dissipated.

At least one stepped arrangement 20, 21, 22, 23 having an associated mating surface 17 serves to minimize this gap dimension 38. This occurs through a relative movement between the connection face 16 of the cooler 12 and the electronic component 26, for example, by a lateral (or planar) displacement 32 or by a rotation 36. The stepped arrangement 20, 21, 22, 23 may be arranged either directly on the cooler 12 (FIG. 1) or on a component connected to the cooler 12 and/or on the electronic component 26 itself or on a component fixedly connected to the electronic component 26, such as the circuit board 24 and/or the housing 18 (FIG. 2) or similar. The stepped arrangement 20, 21, 22, 23 interacts with corresponding mating surfaces 17. The mating surface 17 interacting with the stepped arrangement 20, 21, 22, 23 may be arranged either directly on the cooler 12 (FIG. 2) or on a component connected to the cooler 12 and/or on the electronic component 26 itself or on a component fixedly connected to the electronic component 26, such as the circuit board 24 and/or the housing 18 (FIG. 1) or similar. Typically, a plurality of stepped arrangements 20, 21, 22, 23 and corresponding mating surfaces 17 are present. In this case, for example, there may be four support points arranged at the corners (between the cooler 12 and the housing 18), or three support points for stable support with a minimal surface area.

In the exemplary embodiment according to FIG. 1, the mating surfaces 17 are arranged on the housing 18, which in turn is connected to the circuit board 24 on which the electronic component 26 from which heat is to be dissipated is arranged. The mating surfaces 17 on the housing project slightly outward relative to the surface of the housing 18. The cooler 12 is initially arranged so as to be movable relative to the electronic component 26 from which heat is to be dissipated, in particular, in a direction that influences the gap dimension 38 between the surface of the electronic component 26 from which heat is to be dissipated and the connection face 16 of the cooler 12.

The cooler 12 has, on each side, a projection 13 which on the side covers the surface of the housing 18 and projects over the opening 19 of the housing, in effect acting as a collar or rim. In particular, the stepped arrangement 20, 21 may be provided on the projection 13 of the cooler 12, for example, in the form of a plurality of steps and discrete distance variations relative to the connection face 16 and/or the mating surface 17 or mating surfaces 17.

In the exemplary embodiment according to FIG. 1, the stepped arrangement 20, 21 on the cooler 12 consists, for example, of a plurality of, for instance three, steps, wherein the steps are oriented toward the housing 18 with different heights d1, d2, d3. On another side of the cooler 12 there is likewise a further stepped arrangement 21, for example, in the form of further, for example, three, steps having the same heights d1, d2, d3. The two stepped arrangements 20, 21 of the cooler 12, or the two regions having steps, are each oriented, relative to the plane of the connection face 16 and with respect to the direction of the lateral displacement 32 and/or a rotation 36 described later, in an ascending or descending manner. The height d1, d2, d3 of the respective, in particular, opposing, steps either increases or decreases continuously, such that a relative movement 32 parallel to the plane of the connection face 16 leads either to an increase or to a decrease of the distance or the gap dimension 38 between the connection face 16 and the surface of the electronic component 26 from which heat is to be dissipated.

By way of example, projecting surfaces such as cooling fins 14 are provided on the cooler 12 in order to release, as an air cooler, the heat to be dissipated effectively to the surroundings. However, other cooling principles may be provided, such as a liquid cooler having, for example, circulating water as a cooling medium, etc. For example, the cooler 12 may be made of a particularly thermally conductive material such as copper, or may be configured as a vapor chamber (a sealed space filled with a thermally conductive medium which, through phase change, ensures particularly efficient heat dissipation) or the like.

The exemplary embodiment according to FIG. 2 shows stepped arrangements 22, 23 arranged on the housing 18. These steps project upward beyond the top surface of the housing 18. The stepped arrangement 22, 23 interacts with a respective mating surface 17 on the cooler 12. This mating surface 17 is arranged on the outside of the projection 13 that covers the opening 19 of the housing 18. This projection 13 ends in an rim region that includes the mating surface 17, which extends in the direction of the housing 18 and thus also covers the further projecting steps of the stepped arrangement 22, 23 without being in engagement.

At the outset, the mating surface 17 is arranged, for example, on the second step from the inside of the stepped arrangement 22, 23, or on a section that produces a relatively large gap dimension 38; see the bottom illustration of FIG. 2. The initial positioning on a middle step of the stepped arrangement 22, 23 is particularly advantageous, since, if necessary, without a large change in position or displacement 32, the minimum gap dimension 38 may be achieved particularly simply from the middle position.

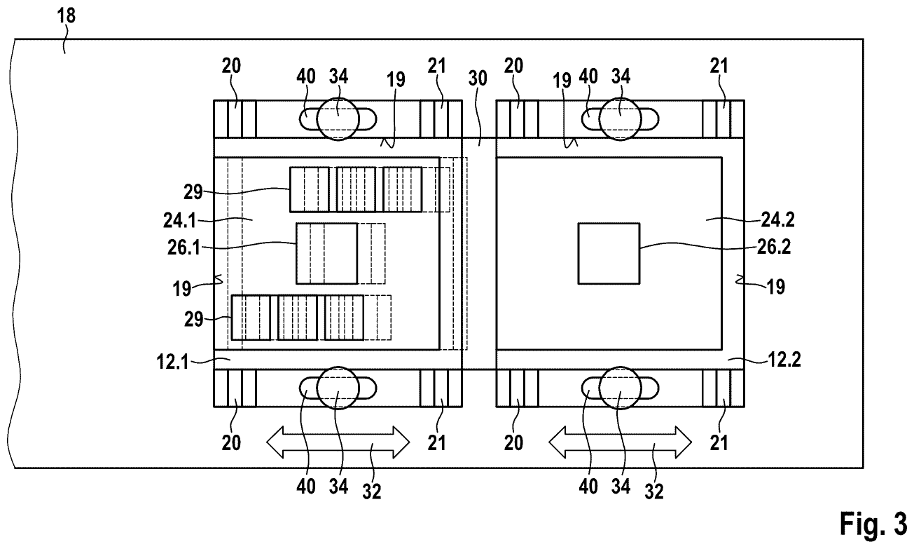

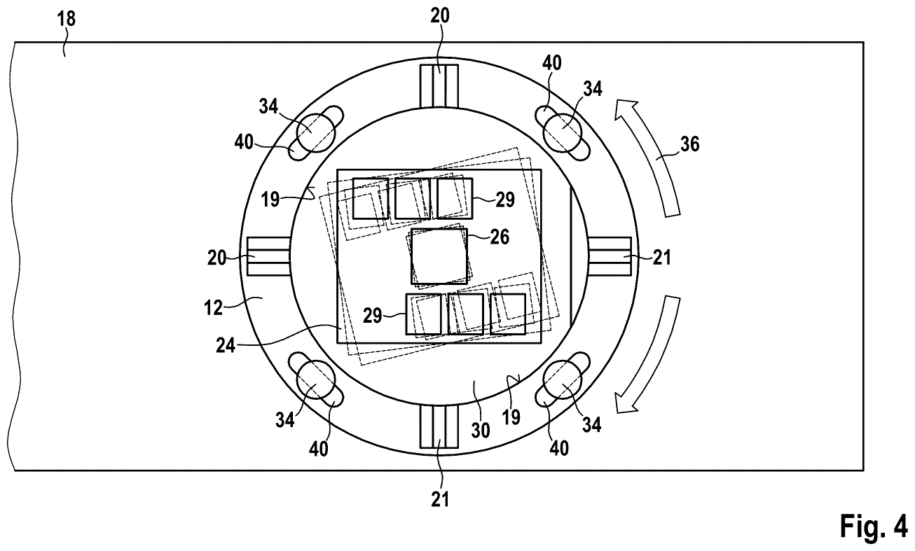

The distance (gap dimension 38) from the surface of the electronic component 26 to the support point of the cooler 12 or the connection face 16 is measured, following installation of the circuit board 30, 24 in the housing 18, through the opening 19 in the housing 18. It may then be determined on which step of the stepped arrangement 22, 23 the cooler 12 may be placed. For example, as may be seen in FIG. 2, this may be changed by a planar movement 32. If, for example, the cooler 12 is to sit deeper in the housing 18 (reducing the gap dimension 38), it is positioned a short distance further to the left (for example, a few millimeters depending on the step geometry) and thereby placed on a lower step of the stepped arrangement 22, 23. This results in an actual gap dimension 38 (the original gap dimension 38 reduced by d1, wherein dl represents the height difference of the adjacent steps). If the gap dimension 38 is to be reduced further, the cooler 12 may be set further to the left onto a lower step of the stepped arrangement 22, 23 on the housing 18, such that, according to the upper drawing of FIG. 2, an actual gap dimension 38 is established from the difference between the original gap dimension 38 and d2 (d2 being a height difference between the original step and the actual step). After measurement and precise positioning, the cooler 12 is conventionally installed, for example, under force-displacement control, using thermally conductive material 28 (for example, a TIM dispense), pressed on, and then fixed, for example, screwed in place (for example, by fastening means 34 such as screws, as shown by way of example in FIGS. 3 and 4).

In the top view according to FIG. 3, it may be seen that a lateral offset or displacement 32 produces an overlap or lateral offset of the respective electronic components 26; 26.1, 26.2; 29. This overlap, or the generally possible maximum lateral displacement, must be selected such that, at all step positions, all electronic components 26; 26. 1, 26.2; 29 may be adequately thermally coupled. It may further be seen from FIG. 3 that, by way of example, two smaller circuit boards 24.1, 24.2, each having at least one electronic component 26.1, 26.2 from which heat is to be dissipated, are arranged on the further circuit board 30. For each circuit board 24.1, 24.2 or each electronic component 26. 1, 26.2 from which heat is to be dissipated, a cooler 12.1, 12.2 is provided having stepped arrangements 20, 21 arranged in the corner regions (either arranged on the housing 18 or on the cooler 12 as described in connection with FIGS. 1 and 2; only the projection 13 of the cooler 12 is shown schematically as transparent such that the positions of the stepped arrangements 20, 21 are apparent), each of which may be displaced individually by a lateral linear movement 32 for adjusting the optimal gap dimension 38. Also shown schematically are fastening means 34 which, due to the possible displaceability of the cooler 12 relative to the housing 18, are, in each case, received in an oversized through-hole or in an elongated hole 40. These fastening means 34 serve for the final fixing of the cooler 12 relative to the electronic component 26 when the suitable gap dimension 38 has been found following the suitable arrangement of the mating surface 17 on the suitable step of the stepped arrangement 20, 21. The oversized through-holes or elongated holes 40 (with washer, etc.) allow different fastening positions of the fastening means 24 as a function of the different gap dimensions 38 or the varying extents of lateral displacement 32. Preferably, a corresponding thread is formed in the housing 18 for fastening, wherein the oversized through-hole or elongated hole 40 is arranged on the cooler 12, through which the fastening means 34 is guided and connected to the housing 18, for example, by screwing.

In the exemplary embodiment according to FIG. 4, a change of the gap dimension 38 may be brought about by a rotation 36. For this purpose, the cooler 16 arranged in the opening 19 is preferably of circular design (as is the opening 19). At the rim regions or projections 13, which cover the housing 18, there are again stepped arrangements 20, 21. As mentioned at the outset, the stepped arrangements 20, 21 may be arranged on the cooler 12 and/or on the housing 18 connected to the electronic component 26. In the exemplary embodiment, for example, four stepped arrangements 20, 21 are provided to ensure sufficient mechanical stability. Between the stepped arrangements 20, 21, corresponding fastening means 34 are provided, wherein the elongated holes 40 (formed, in particular, in a partial circular shape) allow a rotational movement 36 to a certain extent also relative to the fastening means 34.

The stepped arrangements 20, 21, 22, 23 may comprise a plurality of steps and/or plateaus and/or offsets, such that discrete changes of the gap dimension 38 may be achieved. The contact surfaces between the respective stepped arrangements 20, 21, 22, 23 and the corresponding mating surfaces 17; 22, 23 may be formed in a linear, point-shaped, circular, rectangular, or other suitable form.

Along the connection face 16, an EMC seal such as FIPG (Form in Place Gasket, liquid during assembly), CIPG (Cured in Place Gasket, cured during assembly), FoF (Fabric over Foam, fabric tube over a foam core), tape, foam core, springs, or similar may be introduced or arranged between the cooler 12 and the housing 18 such that the housing 18 is completely electrically shielded.

In particular, the electronic components 26 include high-performance computing cores that assume particularly computation-intensive functions in the motor vehicle. For example, these may be autonomous or semi-autonomous driving functions, infotainment, communication interfaces between different bus systems (Ethernet, CAN, LIN, etc.) or gateway functionalities, certain security applications for granting authorization, for example, to access the motor vehicle from outside, or other operations in the motor vehicle associated with particularly high computing power. More preferably, the electronic components 26 are high-performance processors, multi-core processors, or highly integrated circuits (SoC, System on Chip), which are characterized by high power losses. More preferably, the two electronic components 26 arranged on the respective circuit boards 24 are configured to be functionally redundant. In the event of failure of one electronic component 26, the other electronic component 26 may assume the functionality of the failing electronic component 26.

1-14. (canceled)

15. A device for dissipating heat from an electronic component of a motor vehicle, comprising:
at least one cooler having at least one connection face, wherein the connection face is configured such that the electronic component arranged on a circuit board may be cooled via the connection face; and
at least one housing which at least partially encloses the circuit board, wherein the housing has at least one housing opening, wherein at least a portion of the cooler extends out of the housing opening, wherein a gap dimension between the electronic component and the connection face is configured to be adjustable in different steps via at least one stepped arrangement.

16. The device according to claim 15, wherein the stepped arrangement is arranged: (i) on the cooler and/or (ii) on the electronic component and/or (iii) on the housing and/or (iv) on a component connected to the electronic component including the circuit board or another circuit board.

17. The device according to claim 15, wherein at least one mating surface is provided, which interacts with the stepped arrangement for adjustment of the gap dimension, wherein the mating surface is arranged: (i) on the cooler and/or (ii) on the electronic component and/or (iii) on the housing and/or (iv) on a component connected to the electronic component including the circuit board or another circuit board.

18. The device according to claim 15, wherein: (i) the stepped arrangement includes a plurality of steps and/or plateaus and/or offsets, and/or (ii) a further stepped arrangement is provided.

19. The device according to claim 15, wherein the stepped arrangement has a plurality of steps of different height.

20. The device according to claim 17, wherein the gap dimension is variable via a relative movement: (i) between the cooler and the housing and/or (ii) between the mating surface and the stepped arrangement.

21. The device according to claim 20, wherein the relative movement takes place: (i) via an at least substantially linear or planar movement parallel to the surface of the connection face and/or (ii) via a rotation.

22. The device according to claim 20, wherein the relative movement is a linear movement and/or a rotation, and wherein along the relative movement, a height of steps of the stepped arrangement and/or of a further stepped arrangement changes discretely.

23. The device according to claim 17, wherein the stepped arrangement and/or the mating surface interacting with the stepped arrangement is arranged on a rim or projection of the cooler covering the housing opening.

24. The device according to claim 17, wherein the mating surface interacting with the stepped arrangement is formed so as to project beyond a surface in such a manner that the mating surface covers at least parts of the stepped arrangement.

25. The device according to 15, wherein following adjustment of the gap dimension, at least one connector is provided for fixing the cooler relative to the electronic component, wherein the connector effects a fixation compensating for the relative movement and interacts with an oversized hole or elongated hole.

26. A method for dissipating heat from an electronic component of a motor vehicle, the method comprising:
providing a device, including:
at least one cooler having at least one connection face, wherein the connection face s configured such that the electronic component arranged on a circuit board may be cooled via the connection face, and
at least one housing which at least partially encloses the circuit board, wherein the housing has at least one housing opening, wherein at least a portion of the cooler extends out of this housing opening; and
adjusting a gap dimension between the electronic component and the connection face in different steps via at least one stepped arrangement.

27. The method according to claim 26, further comprising:
measuring the gap dimension;
ascertaining an adjustment of the stepped arrangement via a respective step;
applying a relative movement between the cooler and the electronic component to adjust the gap dimension and/or fixing the cooler relative to the electronic component.

28. The method according to claim 26, wherein: (i) the cooler is positioned and/or a thermally conductive material is applied between the cooler and the electronic component, and/or (ii) the cooler is pressed onto a thermally conductive material, and/or (iii) the cooler is fixedly connected to the housing and/or the circuit board, and/or (iv) an EMC seal is introduced between the cooler and the housing.
